(19) United States
(12) Patent Application Publication
(10) Pub. No.: US 2003/0031278 A1
(43) Pub. Date: Feb. 13, 2003

(54) Channel decoding apparatus and method in an orthogonal frequency division multiplexing system

(75) Inventors: Chung-Gu Kang, Seoul (KR); Seung-Young Park, Seoul (KR); Bo-Seok Seo, Seoul (KR); Jung-Je Son, Songnam-shi (KR)

Correspondence Address: Paul J. Farrell, Esq., DILWORTH & BARRESE, LLP, 333 Earle Ovington Blvd., Uniondale, NY, 11553, US

(73) Assignee: SAMSUNG ELECTRONICS CO., LTD., KYUNGKI-DO (KR)

(21) Appl. No.: 10/144,399

(22) Filed: May 13, 2002

(30) Foreign Application Priority Data
May 11, 2001 (KR) 2001-25944

(51) Int. Cl. H03D 1/00

(52) U.S. Cl. 375/341; 714/795

(57) ABSTRACT

A decoding apparatus and method in an OFDM (Orthogonal Frequency Division Multiplexing) communication system. In the OFDM system, a channel with a given frequency band is divided into a plurality of sub-channels spaced from one another in predetermined intervals, pilot symbols are transmitted on predetermined sub-channels, and data symbols are transmitted on the other sub-channels. A channel estimator generates a first channel estimate for each of the data symbols using the pilot symbols, a log likelihood ratio calculator calculates the reception probability of each information bit in the data symbol based on the first channel estimate, and a decoder generates the estimated probability values of the information bits based on the reception probability values of the information bits in the data symbol. Then, the channel estimator generates a second channel estimate for the data symbol based on the estimated probability values of information bits in the data symbol and updates the first channel estimate with the second channel estimate.

### PRIORITY

This application claims priority to an application entitled “Channel Decoding Apparatus and Method in an Orthogonal Frequency Division Multiplexing System” filed in the Korean Industrial Property Office on May 11, 2001 and assigned Serial No. 2001-25944, the contents of which are hereby incorporated by reference.

### BACKGROUND OF THE INVENTION

1. Field of the Invention

The present invention relates generally to an OFDM (Orthogonal Frequency Division Multiplexing) communication system, and in particular, to a channel decoding apparatus and method using a MAP (Maximum A Posteriori) algorithm.

2. Description of the Related Art

OFDM, which has recently been used for high-rate data transmission on wired and radio (wireless) channels, is a kind of multi-carrier modulation (MCM) in which a serial symbol sequence is converted to parallel symbol sequences and modulated with multiple orthogonal sub-carriers (or sub-channels) prior to transmission.

The first systems using MCM were military HF radio links in the late 1950s and early 1960s. A special form of MCM, OFDM, having densely spaced sub-carriers with overlapping spectra of a modulation signal, was developed in the 1970s, but the challenging task of achieving orthogonal modulation between multiple carriers made actual OFDM system implementation difficult. However, in 1971, Weinstein and Ebert applied DFT (Discrete Fourier Transform) to parallel data transmission systems as part of the modulation and demodulation processes, which dramatically accelerated the development of OFDM. The introduction of insertion of guard intervals represented by cyclic prefixes has further reduced adverse influence of multipath fading and delay spread on OFDM systems. Thus, OFDM has become widespread to digital transmission applications such as DAB (Digital Audio Broadcasting), digital TV broadcast, and WATM (Wireless Asynchronous Transfer Mode). While OFDM did not find wide use due to hardware complexity, it is now widely implemented along with advanced digital signal processing technology including FFT (Fast Fourier Transform) and IFFT (Inverse Fast Fourier Transform). While OFDM is similar to FDM (Frequency Division Multiplexing), it ensures orthogonality between multiple sub-carriers in transmission. Therefore, the resulting high frequency use efficiency from frequency spectral overlap and resistance against frequency selective fading and multipath fading lead to the best transmission efficiency in high rate data transmission. Furthermore, OFDM reduces inter-symbol interference (ISI) by the use of guard intervals, simplifies equalizers in hardware, and exhibits robustness against impulse noise. Hence OFDM is widely being adopted in communication systems.

FIG. 1 is a block diagram of a transmitter in a typical OFDM communication system. Referring to FIG. 1, upon input of information data, an encoder (not shown) encodes the information data by a predetermined encoding method. An interleaver interleaves the coded data in an interleaver (not shown) to prevent burst errors. The interleaved information data I(l, k) is serial data. A serial-to-parallel converter (S/P) 111 generates a plurality of sub-channels by arranging the serial information data I(l, k) in parallel. A pilot inserter 113 generates preset pilot symbols and inserts them into the sub-channels, that is, the data symbols received from the S/P 111, for channel estimation in a receiver. The pilot symbols, that is, pilot sub-channels are arranged in predetermined transmission positions. The pilot symbol insertion will be described with reference to FIG. 2.

FIG. 2 illustrates an example of pilot symbol insertion in the pilot inserter 113 illustrated in FIG. 1. Referring to FIG. 2, reference character l denotes a burst index representing an OFDM frame, and reference character k denotes a carrier index representing a sub-channel in the OFDM frame, that is, a sub-carrier index. One OFDM frame includes a predetermined number of symbols. For example, if there are 16 sub-channels, one OFDM frame includes 16 symbols. As illustrated in FIG. 2, pilot symbols are inserted in every Mₜ OFDM frames. The pilot symbols are spaced by M_{f} sub-channels within one OFDM frame. If Mₜ=8 and M_{f}=4, pilot symbols are inserted to the 1^{st}, 9^{th}, 17^{th}, . . . OFDM frames and within each of the OFDM frames, the pilot symbols are inserted to the 1^{st}, 5^{th}, 9^{th}, . . . sub-channels.

Returning to FIG. 1, an IFFT (Inverse Fast Fourier Transformer) 115, which is a K-point IFFT, frequency-division-multiplexes the output of the pilot inserter 113 and feeds the resulting signal i_{l, n} to a guard interval inserter 117. The inverse fast Fourier transformation of symbols transmitted on the sub-channels is expressed as

$${i}_{l , n} = \frac{\sqrt{{E}_{s}}}{N} {\sum }_{k = 0}^{N - 1} I ( l , k ) {ⅇ}^{\frac{j2π kn}{N}} , 0 \leq n \leq N - 1 \qquad ( 1 )$$

where I(l, k) indicates data transmitted on a kth sub-channel in an lth OFDM frame and i_{l, n} indicates a sequence after inverse fast Fourier transformation.

The guard interval inserter 117 inserts a guard interval into the signal, that is, sub-channels received from the IFFT 115 to reduce the influence of ISI and IFI (Inter-Frame Interference). Each guard interval includes a predetermined number of, for example, N_{G} samples. A parallel-to-serial converter (P/S) 119 converts parallel sub-channel signals received from the guard interval inserter 117 to a serial sequence, which can be expressed as

output data={i_{l,N-N}_{₀}, . . . , i_{l,N-2}, i_{l,N-1}, i_{l,0}, i_{l,I}, . . . , i_{l, N-1}} (2)

An OFDM frame output from the P/S 119 is subjected to RF processing and transmitted.

Now reception of the OFDM frame will be described below. FIG. 3 is a block diagram of a receiver in the typical OFDM communication system.

It is assumed that a channel transmitting the output data of the transmitter illustrated in FIG. 1 has an impulse response calculated by

$$h ( n ) = {\sum }_{i = 0}^{L - 1} {h}_{i} \cdot δ ( n - i ) \qquad ( 3 )$$

where h(n) is a channel characteristic.

Referring to FIG. 3, a signal received on a channel having such an impulse response is applied to the input of an S/P 311. The S/P 311 converts the serial input signal, that is, an OFDM frame to a predetermined number of parallel OFDM symbols. Here, it is assumed that the receiver receives OFDM signals on a frame basis. Then, a guard interval remover 313 removes a guard interval from the parallel OFDM symbols r_{i,n}.

$${r}_{i , n} = {\sum }_{i = 0}^{L - 1} {h}_{i} {i}_{l , n - 1} + {w}_{l , n} ; 0 \leq n \leq N - 1 \qquad ( 4 )$$

where w_{l, n} is a noise component generated during channel transmission.

An FFT (Fast Fourier Transformer) 315 converts the OFDM symbols r_{i, n} received from the guard interval remover 313 to a plurality of sub-channel signals R(l, k) by fast Fourier transformation.

$$\begin{matrix}R ( l , k ) = I ( l , k ) {\sum }_{i = 0}^{L - 1} {h}_{i} {ⅇ}^{\frac{- j2π ik}{N}} + \frac{1}{\sqrt{{E}_{s}}} \cdot {\sum }_{n = 0}^{N - 1} {w}_{l , n} {c}^{\frac{- j2π ik}{N}} \\ = I ( l , k ) \cdot H ( l , k ) + \frac{W ( l , k )}{\sqrt{{E}_{s}}}\end{matrix} \qquad ( 5 )$$

where L should be less than the number N_{G} of samples in the guard interval and H(l, k) is a channel gain.

$$H ( l , k ) = {\sum }_{i = 0}^{L - 1} {h}_{i} {ⅇ}^{\frac{- j2π ik}{N}} \qquad ( 6 )$$

The channel gain H(l, k) can be obtained from N-point fast Fourier transformation of L impulse responses of a channel. For example, if L=10 and N=64, fast Fourier transformation is performed with impulse responses used as the first 10 inputs and zeros used for the remaining 54 inputs, to thereby achieve the channel gain H(l, k).

To detect the information data transmitted by the transmitter from the signal R(l, k) output from the FFT 315, the receiver estimates the channel gain H(l, k) using pilot symbols at a channel estimator 317. A signal compensator & detrminer 319 compensates the output signal of the FFT 315 by using the channel gain H(l, k).The signal is then converted to serial data by P/S 321. A channel gain estimate H(l, k) and the information data I(l, k) are in the following relation.

Ĥ*(l, k)R(l, k)=Ĥ*(l, k)H(l, k)I(l, k) +Ĥ*(l, k)W(l, k) (7)

In Equation (7), the information data I(l, k) can be obtained if it is a PSK (Phase Shift Keying) signal. If the information data I(l, k) is an MQAM (M-ary Quadrature Amplitude Modulation) signal, it is estimated to be |H(l, k)|².

Based on the idea that the channel gain H(l, k) is a function related to the difference between a sub-carrier index and a burst index, the channel gain H(l, k) is estimated using pilot symbols. That is, based on the equation p(m, q)=E{H(l, k)H* (1-m,k-q)}, a channel gain for data symbols is estimated using the pilot symbols transmitted in predetermined intervals.

In a radio channel environment, the receiver in the typical OFDM communication system estimates a channel gain using pilot sub-channels having pilot symbols and recovers the original information data by channel decoding using the channel gain estimate. If the channel gain estimate is not correct, data decoding performance is seriously deteriorated. Channel estimation accuracy increases in proportional to the number of pilot sub-channels. However, the increase of pilot sub-channels in number results in the decrease of information data transmission efficiency because the pilot sub-channels transmit only pilot symbols.

Accordingly, the receiver estimates channels using limited pilot sub-channels. This implies that the channel gain is estimated with limited accuracy and thus channel estimation performance is deteriorated due to the channel gain with limited accuracy. Especially, under a channel environment such as wireless LANs sharing an ISM (Industrial Science Medical) band with other types of systems and pico-cells in future generation systems, SINR (Signal-to-Interference plus Noise Power Ratio) is very low due to interference from nearby systems and channel estimation should be accurate even under this severe channel environment. Since pilot sub-channels are inevitably influenced by such channel environment, a low SINR of the pilot sub-channels deteriorates channel estimation performance.

### SUMMARY OF THE INVENTION

It is, therefore, an object of the present invention to provide a channel decoding apparatus and method for improving channel estimation performance using data symbols in an OFDM communication system.

It is another object of the present invention to provide a channel decoding apparatus and method for improving channel estimation performance using soft-decision values from a MAP algorithm.

It is a further object of the present invention to provide a channel decoding apparatus and method for improving channel estimation performance using both pilot symbols and data symbols.

The foregoing and other objects of the present invention are achieved by providing a decoding apparatus and method in an OFDM communication system. In the OFDM system, a channel with a given frequency band is divided into a plurality of sub-channels spaced from one another in predetermined intervals, pilot symbols are transmitted on predetermined sub-channels, and data symbols are transmitted on the other sub-channels. A channel estimator generates a first channel estimate for each of the data symbols using the pilot symbols, a log likelihood ratio calculator calculates the reception probability of each information bit in the data symbol based on the first channel estimate, and a decoder generates the estimated probability values of the information bits based on the reception probability values of the information bits in the data symbol. Then, the channel estimator generates a second channel estimate for the data symbol based on the estimated probability values of information bits in the data symbol and updates the first channel estimate with the second channel estimate.

In the channel decoding method, a first channel estimate is generated for each of the data symbols using the pilot symbols, the reception probability value of each information bit in each of the data symbols is calculated based on the first channel estimate, the data symbols are decoded by generating estimated probability values of the information bits of the data symbol based on the reception probability values of the information bits and soft-deciding the information bits, a second channel estimate for the data symbol is generated based on the estimated probability values of the information bits, and the first channel estimate is updated with the second channel estimate.

### BRIEF DESCRIPTION OF THE DRAWINGS

The above and other objects, features and advantages of the present invention will become more apparent from the following detailed description when taken in conjunction with the accompanying drawings in which:

FIG. 1 is a block diagram of a transmitter in a typical OFDM communication system;

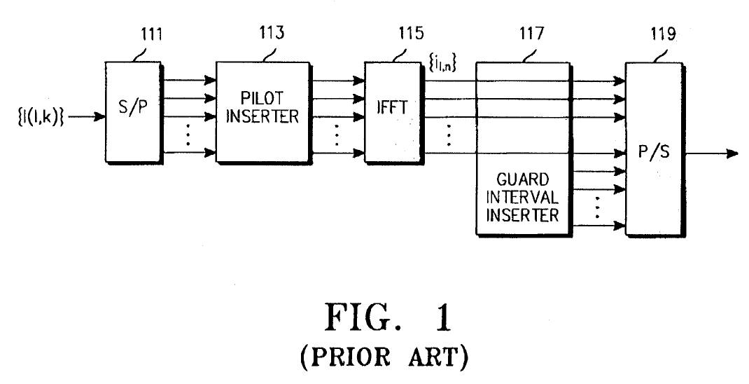

FIG. 2 illustrates an example of pilot symbol insertion in a pilot inserter illustrated in FIG. 1;

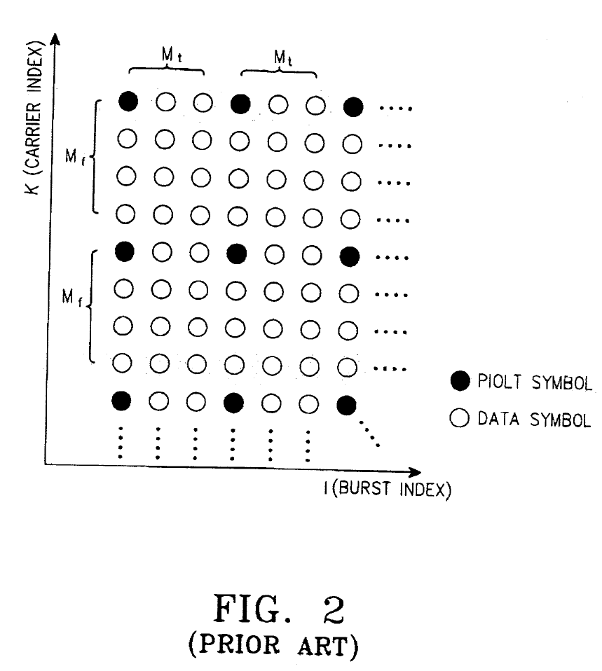

FIG. 3 is a block diagram of a receiver in the typical OFDM communication system;

FIG. 4 is a block diagram of a transmitter in an OFDM communication system according to an embodiment of the present invention; and

FIG. 5 is a block diagram of a receiver in the OFDM communication system to the embodiment of the present invention.

### DETAILED DESCRIPTION OF THE PREFERRED EMBODIMENT

A preferred embodiment of the present invention will be described hereinbelow with reference to the accompanying drawings. In the following description, well-known functions or constructions are not described in detail since they would obscure the invention in unnecessary detail.

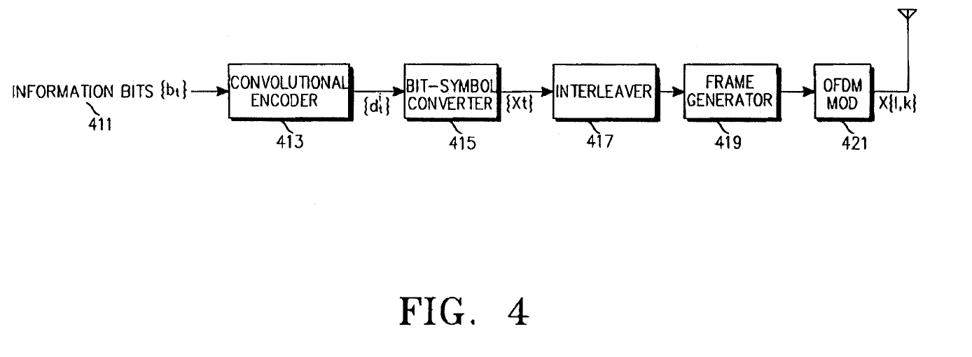

FIG. 4 is a block diagram of a transmitter in an OFDM communication system according to an embodiment of the present invention. Referring to FIG. 4, upon input of information bits {bₜ} 411, a convolutional encoder 413 encodes them by convolutional encoding at a predetermined code rate of 1/R and outputs convolutionally coded information bits {dₜⁱ} (iε{0, 1, 2, . . . , R-1}) to a bit-symbol converter 415. For example, if the information bits {bₜ} 411 are “aa” and the code rate 1/R is ¼, the convolutionally coded information bits {dₜⁱ} are “aaaaaaaa”. While convolutional coding is adopted in the embodiment of the present invention, other encoding methods can be applied, such as turbo coding and Reed-Solomon coding.

The bit-symbol converter 415 converts every R bits of the convolutionally coded information bits {dₜⁱ} to a single MQAM symbol Xₜ. Obviously, PSK or any other modulation can substitute for MQAM.

An interleaver 417 interleaves the MQAM symbols {Xₜ} to prevent burst errors. A frame generator 419 groups the interleaved transmission symbols according to the number of sub-channels. That is, the frame generator 419 divides the successive interleaved symbols into MK-symbol units and generates M successive frames each having K sub-channels. The M frames are produced from information bits to be actually transmitted and the K sub-channels in each frame are data sub-channels of the information bits. One frame including K successive symbols is generated in the frame generator 419 and output to an OFDM modulator 421.

The OFDM modulator 421 modulates the serial frame signal received from the frame generator 419 to a predetermined number of parallel signals, that is, sub-channel signals through an S/P. Pilot sub-channels are inserted into the sub-channels for initial channel estimation. The insertion positions of the pilot sub-channels are preset and known to both the transmitter and a receiver in the OFDM communication system. The data sub-channels and the inserted pilot sub-channels are subject to inverse fast Fourier transformation, a guard interval is inserted between the IFFT sub-channels, and the resulting serial OFDM frame {X_{l, k}} is output. Such M OFDM frames are successively transmitted. X_{l, k} is a kth sub-channel in an lth OFDM frame.

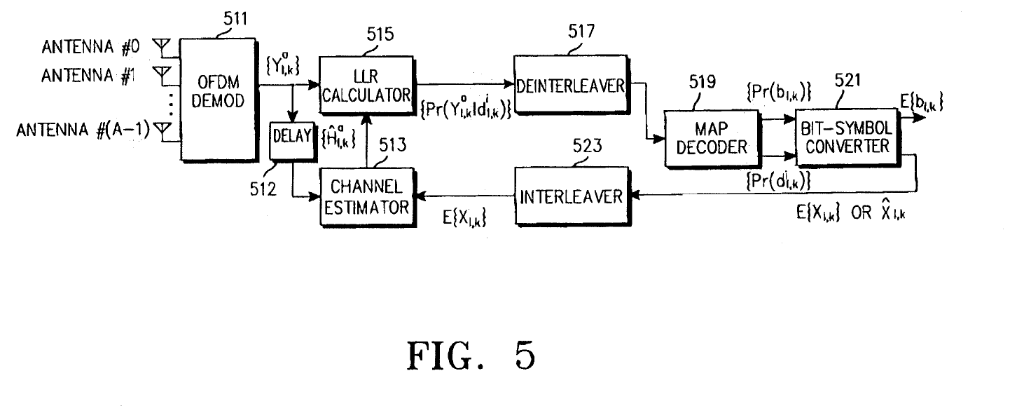

A receiver in the OFDM communication system performs channel estimation and data decoding using the transmission signal received from the transmitter illustrated in FIG. 4. This will be described with reference to FIG. 5.

FIG. 5 is a block diagram of the receiver in the OFDM communication system according to the embodiment of the present invention.

As described in connection with FIG. 4, the M successive OFDM frames transmitted from the transmitter arrive at the receiver through a predetermined number of, for example, A antennas (antennas #0 to #(A-1)) from multiple paths. The received OFDM frames are applied to the input of an OFDM demodulator 511. Although the receiver receives the M successive frames, channel estimation and decoding on a frame basis will be described for clarity of description.

The OFDM demodulator 511 outputs an OFDM frame to an S/P (not shown). The S/P converts the serial OFDM symbols to a predetermined number of parallel signals. A guard interval remover (not shown) removes a guard interval from the parallel signals. An FFT (not shown) fast-Fourier-transforms the parallel signals received from the guard interval remover and feeds the resulting sub-channel signals to a delay 512 and a log likelihood ratio (LLR) calculator 515. The delay 512 delays the sub-channel signals by a predetermined time for timing synchronization to channel estimation. Here, the OFDM demodulator 511 outputs k sub-channel signals from each of the A antennas, represented as {Y_{l,k}^{a}}. {Y_{l,k}^{a}} is an lth symbol delivered by a kth sub-carrier, that is, a kth sub-channel in an lth frame, from an ath antenna.

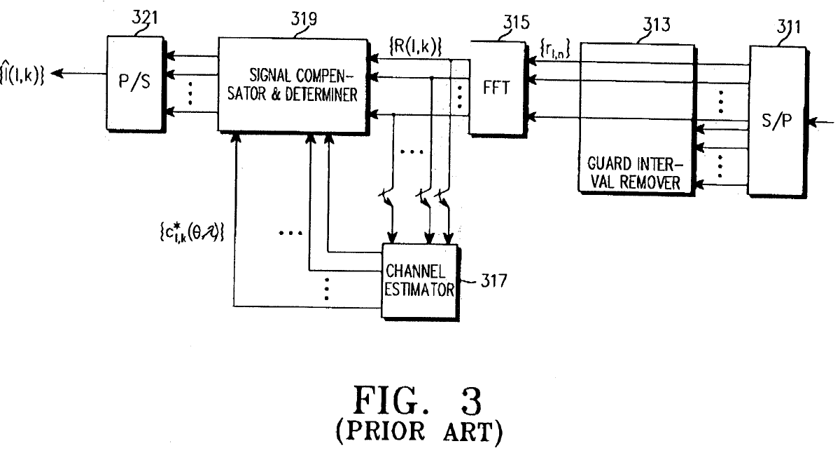

A channel estimator 513 estimates the channel gain {H_{l,k}^{a}} of the frame signal {Y_{l,k}^{a}} from the ath antenna using only pilot sub-channels of the frame signal in the manner described with reference to FIG. 3. The channel gain estimate {Ĥ_{l,k}^{a}} is an initial channel gain estimate.

A LLR calculator 515 calculates the LLR of the transmission bits of the lth symbol on the kth sub-channel using the initial channel gain estimate {Ĥ_{l,k}^{a}} and the signal {Y_{l,k}^{a}}. The LLR is an approximate value of the coded bits of the lth symbol. If the transmitter transmits a signal X and the receiver receives a signal Y, the LLR is the log value of a ratio of X to Y. The LLR is determined by

$$L ( {Y}_{l , k} \vert {d}_{l , k}^{i} ) = log \frac{Pr ( {Y}_{l , k} \vert {d}_{l , k}^{i} = + 1 )}{Pr ( {Y}_{l , k} \vert {d}_{l , k}^{i} = - 1 )}$$

where Y_{l,k}=[Y_{l,k}⁰, Y_{l,k}¹, . . . , Y_{l,k}^{A-1}], d_{l,k}ⁱ is an ith transmission information bit in the lth symbol transmitted by the kth sub-carrier from the transmitter, and Pr is the APP (A Posteriori Probability) of the transmission information bits {d_{l,k}ⁱ}. A MAP decoder 519 determines the values of the information bits {d_{l,k}ⁱ} using the LLR received from the LLR calculator 515. That is, the MAP decoder 519 determines whether each transmission information bit d_{l,k}ⁱ is +1 or −1 using the LLR.

After the LLR calculator 515 calculates the LLR of the signal {Y_{l,k}^{a}} using the initial channel gain estimate {Ĥ_{l,k}^{a}}, the signal {Y_{l,k}^{a}} is fed to a deinterleaver 517. The deinterleaver 517 deinterleaves the signal {Y_{l,k}^{a}} by the reverse operation of the interleaving performed in the transmitter. The MAP decoder 519 decodes the deinterleaved signal using the LLR received from the LLR calculator 515. That is, the MAP decoder 519 determines the value of the information bit transmitted from the transmitter based on the LLR.

The MAP decoder 519 can be replaced with any other decoder as long as it uses the LLR, such as a Viterbi decoder. A bit-symbol converter 521 converts every R bits of information bits received from the MAP decoder 519 to a single MQAM symbol \hat{X}_{l,k}, which is an estimated symbol for the symbol X_{l, k} transmitted from the transmitter. Here, the estimated transmission symbol \hat{X}_{l,k} is a soft-decision value E{X_{l,k}} of the transmission symbol X_{l,k}, expressed as

$$E \{ {X}_{l , k} \} = {\sum }_{{C}_{i} ∈ {Ω}_{C}} {C}_{i} Pr [ {X}_{l , k} = {C}_{i} ] \qquad ( 9 )$$

where Ω_{C} is a set of whole transmission symbols in the frame.

The soft-decision value E{X_{l, k}} is interleaved in an interleaver 523 by the interleaving method used in the transmitter.

The channel estimator 513 multiplies the delayed signal {Y_{l,k}^{a}} received from the delay 512 by the interleaved soft-decision value E{X_{l, k}}. The initial channel gain estimate {Ĥ_{l,k}^{a}} is updated using {Y_{l,k}^{a}}·E{X_{l, k}} in the manner described in connection with FIG. 3.

The channel estimator 513 feeds the updated channel gain estimate {Ĥ_{l,k}^{a}} to the LLR calculator 515. While the initial channel gain estimate {Ĥ_{l,k}^{a}} is calculated using only pilot sub-channels, the updated channel gain estimate {Ĥ_{l,k}^{a}} is obtained using the soft-decision values of information bits transmitted by the transmitter, that is, using data channel symbols as well as pilot symbols. Therefore, the updated channel gain estimate is more accurate because it is calculated using more symbols.

The LLR calculator 515 calculates the LLR of the signal {Y_{l,k}^{a}} using the updated channel gain estimate {Ĥ_{l,k}^{a}} by Equation (8). The deinterleaver 518 deinterleaves the signal output from the LLR calculator 515. The MAP decoder 519 decodes the deinterleaved signal using the updated LLR received from the LLR calculator 515. That is, the MAP decoder 519 determines the values of the information bits transmitted by the transmitter using the updated LLR. The bit-symbol converter 521 generates every R bits of the information bits received from the MAP decoder 519 to a single MQAM symbol \hat{X}_{l,k}.

As described above, the initial channel gain estimate is calculated using pilot symbols only and updated using data symbols as well as the pilot symbols.

Using the updated channel gain estimate, the LLR of a transmission information bit is also updated.

The channel gain estimation or the LLR calculation is repeated predetermined times or until the maximum difference between LLRs L(d_{l,k}ⁱ) is below a predetermined threshold, i.e., max{L^{p+1}(d_{l,k}ⁱ)−L^{p}(d_{l,k}ⁱ)}<threshold . Here, L^{p}(d_{l,k}ⁱ) is L(d_{l,k}ⁱ) at a pth iteration. If the maximum difference between LLRs is below the threshold, this implies that the decoding accuracy of the information bits reaches a level at which no errors are generated. The threshold is preset adaptively to the environment of the OFDM system.

If the above condition is satisfied, the MAP decoder 519 finally decodes the signal {Y_{l,k}^{a}}, that is, recovers the information bits of the signal {Y_{l,k}^{a}} by

$$L ( {b}_{t} ) = log \frac{Pr \{ {b}_{t} = + 1 \}}{Pr \{ {b}_{t} = - 1 \}} .$$

In accordance with the present invention as described above, data symbols as well as pilot symbols are used for channel estimation in an OFDM communication system. The resulting improved channel estimation performance leads to more accurate information data decoding. The additional use of data symbols makes it possible to maintain data transmission efficiency without increasing pilot symbols in number.

While the invention has been shown and described with reference to a certain preferred embodiment thereof, it will be understood by those skilled in the art that various changes in form and details may be made therein without departing from the spirit and scope of the invention as defined by the appended claims.

What is claimed is:

1. A decoding apparatus in an OFDM (Orthogonal Frequency Division Multiplexing) communication system having a channel with a given frequency band divided into a plurality of sub-channels spaced from one another in predetermined intervals, pilot symbols transmitted on predetermined sub-channels, and data symbols transmitted on the other sub-channels, the apparatus comprising:
a channel estimator for generating a first channel estimate for each of the data symbols using the pilot symbols, generating a second channel estimate for each of the data symbols based on estimated probability values of information bits in each of the data symbols, and updating the first channel estimate with the second channel estimate;
a log likelihood ratio calculator for calculating a reception probability of each information bit in the data symbol based on the first channel estimate; and
a decoder for generating the estimated probability values of the information bits based on the reception probability values of the information bits in each of the data symbols.

2. The decoding apparatus of claim 1, wherein the decoder is a MAP (Maximum A Posteriori) decoder.

3. The decoding apparatus of claim 1, further comprising a bit-symbol converter for converting the information bits to symbols by orthogonal amplitude modulation based on the reception probability values of the information bits.

4. The decoding apparatus of claim 1, wherein a reception probability value is calculated by
$$L ( {Y}_{l . k} \vert {d}_{l , k}^{i} ) = log \frac{Pr ( {Y}_{l , k} \vert {d}_{l , k}^{i} = + 1 )}{Pr ( {Y}_{l , k} \vert {d}_{l , k}^{i} = - 1 )}$$
where Y_{l, k} is a signal including the data symbols and the pilot symbols input to the decoding apparatus, and d_{l,k}ⁱ is an ith information bit in an 1th symbol transmitted on a kth sub-channel.

5. The decoding apparatus of claim 1, wherein the first channel estimate updating is repeated a predetermined number of times.

6. The decoding apparatus of claim 1, wherein the first channel estimate updating is repeated until the distance between reception probability values is less than a predetermined threshold.

7. The decoding apparatus of claim 6, wherein the reception probability values are successive.

8. A decoding apparatus in an OFDM (Orthogonal Frequency Division Multiplexing) communication system having a channel with a given frequency band divided into a plurality of sub-channels spaced from one another in predetermined intervals, pilot symbols transmitted on predetermined sub-channels, and data symbols transmitted on the other sub-channels, the apparatus comprising:
a channel estimator for generating a first channel estimate for each of the data symbols using the pilot symbols, generating a second channel estimate for each of the data symbols based on estimated probability values of information bits in each of the data symbols, and updating the first channel estimate with the second channel estimate;
a log likelihood ratio calculator for calculating reception probability value of each information bit in the data symbol based on the first channel estimate;
a deinterleaver for deinterleaving the data symbols and the pilot symbols;
a decoder for generating the estimated probability values of the information bits in each deinterleaved data symbol based on the reception probability values of the information bits;
a bit-symbol converter for converting the information bits to symbols using the reception probability values of the information bits; and
an interleaver for interleaving the symbols.

9. The decoding apparatus of claim 8, wherein the decoder is a MAP (Maximum A Posteriori) decoder.

10. The decoding apparatus of claim 8, wherein the bit-symbol converter converts the information bits to the symbols by orthogonal amplitude modulation based on the reception probability values of the information bits.

11. The decoding apparatus of claim 8, wherein a reception probability value is calculated by
$$L ( {Y}_{l . k} \vert {d}_{l , k}^{i} ) = log \frac{Pr ( {Y}_{l , k} \vert {d}_{l , k}^{i} = + 1 )}{Pr ( {Y}_{l , k} \vert {d}_{l , k}^{i} = - 1 )}$$
where Y_{l, k} is a signal including the data symbols and the pilot symbols input to the decoding apparatus and d_{l,k}ⁱ is an ith information bit in an lth symbol transmitted on a kth sub-channel.

12. The decoding apparatus of claim 8, wherein the first channel estimate updating is repeated a predetermined number of times.

13. The decoding apparatus of claim 8, wherein the first channel estimate updating is repeated until the distance between reception probability values is less than a predetermined threshold.

14. The decoding apparatus of claim 13, wherein the reception probability values are successive.

15. A decoding method in an OFDM (Orthogonal Frequency Division Multiplexing) communication system having a channel with a given frequency band divided into a plurality of sub-channels spaced from one another in predetermined intervals, pilot symbols transmitted on predetermined sub-channels, and data symbols transmitted on the other sub-channels, the method comprising the steps of:
generating a first channel estimate for each of the data symbols using the pilot symbols, generating a second channel estimate for each of the data symbols based on estimated probability values of information bits in each of the data symbols, and updating the first channel estimate with the second channel estimate;
calculating a reception probability of each information bit in the data symbol based on the first channel estimate; and
generating the estimated probability values of the information bits based on the reception probability values of the information bits in each of the data symbols.

16. The decoding method of claim 15, wherein the estimated probability values are generated using a MAP (Maximum A Posteriori) algorithm.

17. The decoding method of claim 15, further comprising the step of converting the information bits to symbols by orthogonal amplitude modulation based on the reception probability values of the information bits.

18. The decoding method of claim 15, wherein a reception probability value is calculated by
$$L ( {Y}_{l , k} \vert {d}_{l , k}^{i} ) = log \frac{Pr ( {Y}_{l , k} \vert {d}_{l , k}^{i} = + 1 )}{Pr ( {Y}_{l , k} \vert {d}_{l , k}^{i} = - 1 )}$$
where Y_{l, k} is a signal including the data symbols and the pilot symbols input to the decoding apparatus, and d_{l,k}ⁱ is an ith information bit in an lth symbol transmitted on a kth sub-channel.

19. The decoding method of claim 15, wherein the first channel estimate updating is repeated a predetermined number of times.

20. The decoding method of claim 15, wherein the channel estimate updating is repeated until the distance between reception probability values is less than a predetermined threshold.

21. The decoding method of claim 20, wherein the reception probability values are successive.

22. A decoding method in an OFDM (Orthogonal Frequency Division Multiplexing) communication system having a channel with a given frequency band divided into a plurality of sub-channels spaced from one another in predetermined intervals, pilot symbols transmitted on predetermined sub-channels, and data symbols transmitted on the other sub-channels, the method comprising the steps of:
generating a first channel estimate for each of the data symbols using the pilot symbols;
calculating a reception probability value of each information bit in each data symbol based on the first channel estimate;
deinterleaving the data symbols and the pilot symbols;
calculating the estimated probability values of the information bits in each deinterleaved data symbol based on the reception probability values of the information bits and soft-deciding the information bits;
converting the information bits to symbols using the reception probability values of the information bits;
interleaving the symbols; and
generating a second channel estimate for the data symbol based on the estimated probability values of the information bits and updating the first channel estimate with the second channel estimate

23. The decoding method of claim 22, wherein the soft decision is performed using a MAP (Maximum A Posteriori) algorithm.

24. The decoding method of claim 22, further comprising the step of converting the information bits to symbols by orthogonal amplitude modulation based on the reception probability values of the information bits.

25. The decoding method of claim 22, wherein a reception probability value is calculated by
$$L ( {Y}_{l , k} \vert {d}_{l , k}^{i} ) = log \frac{Pr ( {Y}_{l , k} \vert {d}_{l , k}^{i} = + 1 )}{Pr ( {Y}_{l , k} \vert {d}_{l , k}^{i} = - 1 )}$$
where Y_{l, k} is a signal including the data symbols and the pilot symbols input to the decoding apparatus and d_{l,k}ⁱ is an ith information bit in an lth symbol transmitted on a kth sub-channel.

26. The decoding method of claim 22, wherein the first channel estimate updating is repeated a predetermined number of times.

27. The decoding method of claim 22, wherein the first channel estimate updating is repeated until the distance between reception probability values is less than a predetermined threshold.

28. The decoding method of claim 27, wherein the reception probability values are successive.
